(19) United States
(12) Patent Application Publication
(10) Pub. No.: US 2019/0012260 A1
(43) Pub. Date: Jan. 10, 2019

(54) FLASH MEMORY PACKAGE AND STORAGE SYSTEM INCLUDING FLASH MEMORY PACKAGE

(71) Applicant: HITACHI, LTD., Tokyo (JP)

(72) Inventors: Atsushi KAWAMURA, Tokyo (JP); Masahiro ARAI, Tokyo (JP); Mitsuhiro OKADA, Tokyo (JP)

(73) Assignee: HITACHI, LTD., Tokyo (JP)

(21) Appl. No.: 15/748,802

(22) PCT Filed: Aug. 4, 2015
(86) PCT No.: PCT/JP2015/072089

§ 371 Date: Jan. 30, 2018

(51) Int. Cl. G06F 12/02; G11C 16/04; G06F 3/06

(52) U.S. Cl. CPC G06F 12/0246; G11C 16/0408; G06F 2212/7211; G06F 3/0659; G06F 3/064

(57) ABSTRACT

A flash memory package has a controller and at least one memory including a flash memory. The controller stores received write data in a primary storage area, which is a partial storage area of the memory, sets the unit of storage area including the plurality of physical pages as the unit of collective transfer to perform collective transfer and, when a volume of data accumulated in the primary storage area is equal to or larger than the capacity of one unit of collective transfer of the flash memory, collectively transfers a volume of data corresponding to the capacity of at least one unit of collective transfer from the primary storage area to a secondary storage area, which is a partial storage area of the flash memory.

### TECHNICAL FIELD

The present invention generally relates to storage control and relates to a technology of a flash memory package (FMPKG), for example.

### BACKGROUND ART

FMPKG which uses a NAND-type flash memory (FM) as a storage medium will be described. A storage area of an FM includes a plurality of physical blocks. The physical blocks each include a plurality of physical pages. The physical block is the unit of data erasure. A physical page is the unit of data read/write. Data stored in a physical page of an FM cannot be rewritten directly. Thus, an FMPKG rewrites data in the following manner.

The FMPKG copies data in a rewrite target physical page to a Dynamic Random Access Memory (DRAM) and rewrites data on the DRAM. The FMPKG stores the rewritten data in another free physical page and invalidates the rewrite target physical page.

The FMPKG performs the following process in order to put the invalidated physical page into a reusable state. All pieces of valid data in the physical block are copied to a free physical page. Moreover, all pieces of data in the physical block are erased. In this way, the physical pages in the physical block become free physical pages and can be reused. This process is referred to as a reclamation process.

A data retention ability of cells in an FM tends to deteriorate with an increase in the number of writes and the number of erasures due to the properties thereof. When the data retention ability deteriorates greatly, a physical block including the deteriorated cell cannot be used (reaches its service life). Therefore, the FMPKG levels off the numbers of writes and the numbers of erasures of respective physical blocks so that the number of writes and the number of erasures of a specific physical block do not become too large. This process is referred to as a wear leveling process.

A read error rate of data retained in the cell of an FM tends to increase with the lapse of time. Such an error is referred to as a retention error. Therefore, the FMPKG copies data of a physical page to another physical page after a predetermined time has elapsed after the data was written. This process is referred to as a refresh process.

In recent years, in order to reduce the cost per unit bit of an FM, finer, multi-level, and three-dimensional FMs are developed. Accordingly, interference (referred to as “intercell interference”) between floating gates of adjacent cells occurs inside an FM (PTL 1 and 2).

### CITATION LIST

### Patent Literature

[PTL 1]

U.S. Pat. No. 7,221,589

[PTL 2]

US2007/0279989

### SUMMARY OF INVENTION

### Technical Problem

Intercell interference tends to increase a read error rate of data retained in the cells of an FM. Therefore, an object of the present invention is to reduce intercell interference in a flash memory package.

### Solution to Problem

A flash memory package according to an embodiment includes a controller, and at least one memory including a flash memory. The flash memory includes a plurality of physical blocks, each of the physical blocks is the unit of data erasure, the physical blocks each include a plurality of physical pages, and each of the physical pages is the unit of data write.

The controller stores received write data in a primary storage area, which is a partial storage area of the memory, and, when a volume of data accumulated in the primary storage area is equal to or larger than a capacity of one physical block of the flash memory, collectively transfers a volume of data corresponding to the capacity of at least one physical block from the primary storage area to a secondary storage area, which is a partial storage area of the flash memory.

### Advantageous Effects of Invention

According to the present invention, it is possible to reduce intercell interference in a flash memory package.

### BRIEF DESCRIPTION OF DRAWINGS

FIG. 1 illustrates a configuration example of a computer system.

FIG. 2 illustrates a configuration example of an FMPKG according to Embodiment 1.

FIG. 3 illustrates an example of programs and data retained in a memory.

FIG. 4 illustrates a configuration example of an FM.

FIG. 5 illustrates a storage example of data in an FM of a Multiple Level Cell (MLC).

FIG. 6 illustrates a configuration example of a cell of an FM.

FIG. 7 illustrates a processing example of transferring data to an FM in an FMPKG.

FIG. 8 illustrates a configuration example of a conventional logical/physical conversion table.

FIG. 9 illustrates a configuration example of a block conversion table and a page conversion table.

FIG. 10 illustrates an example of a flowchart of a write process in an FMPKG.

FIG. 11 illustrates an example of a flowchart of a process of securing a primary storage area.

FIG. 12 illustrates an example of a flowchart of a collective transfer process.

FIG. 13 illustrates an example of a flowchart of a process of securing an empty block in a secondary storage area.

FIG. 14 illustrates an example of a flowchart of a process of saving data in a buffer memory.

FIG. 15 illustrates a configuration example of an FMPKG according to Embodiment 2.

FIG. 16 illustrates an example of a flowchart of a write process in an FMPKG.

FIG. 17 illustrates an example of a flowchart of a reclamation process in a primary storage area.

FIG. 18 illustrates a configuration example of an FMPKG according to Embodiment 3.

FIG. 19 illustrates a configuration example of a block management table and an area management table.

FIG. 20 illustrates a configuration example of a Single Value Cell (SLC) queue and an MLC queue.

FIG. 21 illustrates an example of a flowchart of a collective transfer process.

FIG. 22 illustrates an example of a flowchart of a process of adjusting an MLC area and an SLC area.

### DESCRIPTION OF EMBODIMENTS

Hereinafter, embodiments will be described. In the following description, although information is sometimes described using an expression such as an “xxx table” or an “xxx queue”, the information may be expressed by any data structure. That is, the “xxx table” or the “xxx queue” can be referred to as “xxx information” to show that the information does not depend on the data structure.

In the following description, there may be cases where a process is described using a “program” as the subject. However, since a given process is performed while using at least one of a storage resource (for example, a memory) and a communication I/F device as necessary when a program is executed by a processor (for example, Central Processing Unit (CPU)), the processor or an apparatus having the processor may also be used as the subject of the process. A part or all of the processes performed by the processor may be performed by a hardware circuit. A computer program may be installed from a program source. The program source may be a program distribution server or a storage medium (for example, a portable storage medium).

In the following description, a set of one or more computers that manage at least one apparatus included in a computer system is sometimes referred to as a “management system”. When a management computer displays the display information, the management computer may be a management system. Moreover, a combination of the management computer and the display computer may be a management system. Moreover, a plurality of computers may perform the processes equivalent to those by the management computer in order to improve the speed and the reliability of management processes. In this case, the plurality of computers (including the display computer when the display computer displays the display information) may be a management system. In the present embodiment, the management computer is a management system. Moreover, the management computer displaying information may mean displaying information on a display device included in the management computer and may mean transmitting display information to a display computer (for example, a client) coupled to the management computer (for example, a server). In the latter case, the display computer displays information indicated by the display information on the display device included in the display computer.

Moreover, in the following description, when the same types of elements are described while being distinguished from each other, alphabet as reference numerals may be used like “aaa 113a”, “aaa 113b”, “aaa 201-1”, and “aaa 201-2” and when the same types of elements are described without being distinguished from each other, only a common number of the reference numerals may be used like “aaa 113” and “aaa 201”.

### Embodiment 1

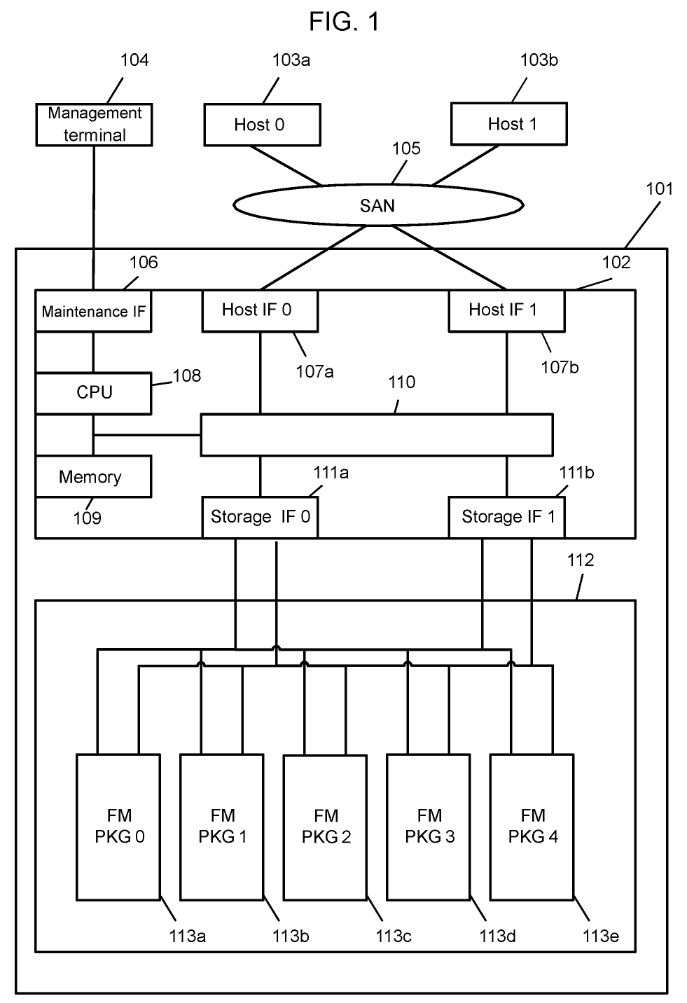

FIG. 1 illustrates a configuration example of a computer system according to Embodiment 1.

The computer system may include a storage system 101, one or more host computers 103a and 103b, and a management terminal 104. The host computers 103a and 103b are coupled so as to be able to perform bidirectional communication with the storage system 101 via a SAN (Storage Area Network) 105 which is an example of a network.

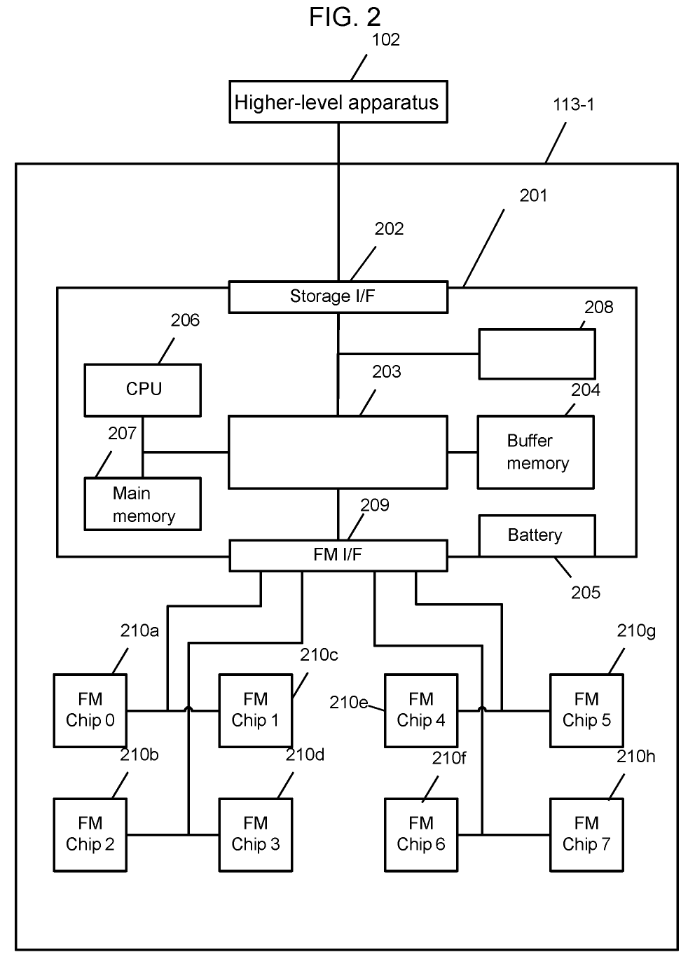

The storage system 101 includes one or more storage controllers 102 and one or more storage apparatuses 112. The storage apparatus 112 may include a plurality of FMPKGs 113a to 113e. The FMPKG 113 is a nonvolatile storage device including a plurality of FM chips. The details of the FMPKG 113 will be described later (see FIG. 2).

The storage controller 102 may include a CPU 108, a memory 109, a plurality of host I/Fs 107, a plurality of storage I/Fs 111, and a maintenance I/F 106. These elements may be coupled so as to be able to perform bidirectional communication via an internal bus 110.

The memory 109 retains programs and data for realizing various functions of the storage system 101. The memory 109 may have a cache area for temporarily retaining read data and write data.

The CPU 108 realizes various functions of the storage system 101 by reading and executing programs and data from the memory 109.

The host I/F 107 is an I/F for allowing the storage controller 102 to communicate with the host computer 103.

The maintenance I/F 106 is an I/F for allowing the storage controller 102 to communicate with the management terminal 104. An administrator may perform management, maintenance, and the like of the storage controller 102 from the management terminal 104.

The computer system may not necessarily have all of these constituent elements. For example, when the management terminal 104 is not included, an administrator may perform management, maintenance, and the like of the storage controller 102 from the host computer 103. The storage controller 102 may not necessarily have all of these constituent elements. The computer system may have a configuration in which the host computer 103 is directly coupled to the FMPKG 113 rather than a configuration in which the host computer 103 and the FMPKG 113 are coupled via the storage controller 102 as illustrated in FIG. 1.

FIG. 2 illustrates a configuration example of an FMPKG 113-1.

The FMPKG 113-1 includes an FM controller 201 and one or more FMs 210a to 210h.

The FM controller 201 may include a storage I/F 202, a buffer memory 204, a battery 205, a CPU 206, a main memory 207, and an FM I/F 209. These constituent elements may be coupled so as to be able to perform bidirectional communication via the internal bus 203.

The storage I/F 202 is an I/F for allowing the FM controller 201 to communicate with a higher-level apparatus 102. An example of the higher-level apparatus 102 is the storage controller 102. Examples of the storage I/F 202 include I/Fs for Serial ATA (SATA), Serial Attached SCSI (SAS), Fibre Channel (FC), or PCI-Express.

The FM I/F 209 is an I/F for allowing the FM controller 201 to transmit and receive data to and from the FM 210.

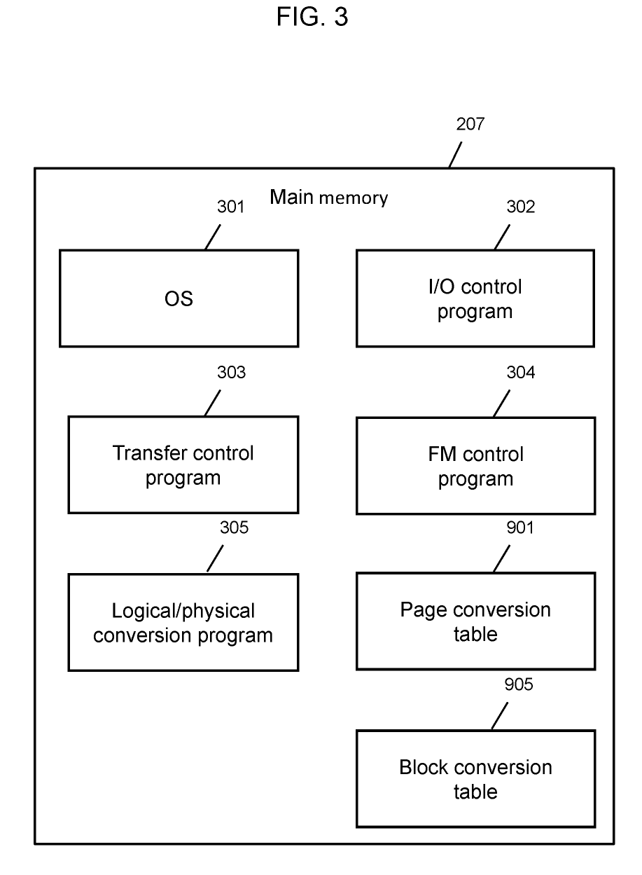

The main memory 207 retains programs and data for realizing various functions of the FMPKG 113-1. Examples of programs and data retained by the main memory 207 will be described later (see FIG. 3).

The buffer memory 204 temporarily retains write data transmitted from the higher-level apparatus 102. The buffer memory 204 may temporarily retain read data read from the FM 210. The buffer memory 204 may also function as a cache memory that caches write data and read data in order to enhance a response function with respect to the higher-level apparatus 102. The buffer memory 204 may retain a large volume of tables which cannot be stored in the main memory 207.

The main memory 207 and the buffer memory 204 may be configured as a volatile storage medium which has a faster access speed (a smaller latency) than the FM 210. An example of the main memory 207 and the buffer memory 204 is SRAM or DRAM.

The CPU 206 realizes various functions of the FMPKG 113-1 by reading and executing programs and data from the main memory 207. Upon receiving a write command from the higher-level apparatus 102, the CPU 206 may store the write data associated with the write command in the FM 210. Upon receiving a read command from the higher-level apparatus 102, the CPU 206 may read the read data associated with the read command from the FM 210 and transfer the read data to the higher-level apparatus 102. The CPU 206 may perform a reclamation process and a wear leveling process depending on a use state of the FM 210. An operation of which the subject is the FM controller 201 in the embodiment may be a process that the CPU 206 performs in cooperation with other constituent elements.

The battery 205 supplies electric power to respective constituent elements of the FM controller 201 when emergency power shutdown occurs. This is to prevent the data retained in the main memory 207 and the buffer memory 204 configured as a volatile storage medium from being erased due to emergency power shutdown. The battery 205 may be referred to as a capacitor.

An assist circuit 208 performs specific data processing on behalf of the CPU 206. Examples of the assist circuit 208 include a data compression circuit, an encryption circuit, a hash calculation circuit, and a code calculation circuit. Although the present embodiment is described without using the assist circuit 208, some of the functions associated with the present embodiment may be performed by the assist circuit 208. The functions of the assist circuit 208 may be realized as a dedicated circuit and may be realized as a program executed by the CPU 206.

The FM controller 201 may not necessarily have all of these constituent elements. The main memory 207 and the buffer memory 204 may be one storage device. As will be described in another embodiment, the main memory 207 or the buffer memory 204 may be configured as a nonvolatile storage medium.

FIG. 3 illustrates an example of programs and data retained in the main memory 207.

The main memory 207 has an OS (Operating System) 301, an FM control program 304, a transfer control program 303, an input/output control program 302, a logical/physical conversion program 305, a page conversion table 901, and a block conversion table 905.

The OS 301 performs a basic process (scheduling, resource management, and the like) when the CPU 206 executes respective programs.

The I/O control program 302 controls the storage I/F 202 and the FM I/F 209.

The FM control program 304 controls all constituent elements of the FMPKG 113-1 and realizes various functions of the FM controller 201. The subject of operations performed by the FM controller 201 in the embodiment may be the FM control program 304 or the CPU 206 that executes the FM control program 304.

The FM control program 304 realizes a function for allowing the FMPKG 113-1 to operate as a storage device. For example, the FM control program 304 provides a logical volume to the higher-level apparatus 102. The logical volume may include a plurality of logical pages.

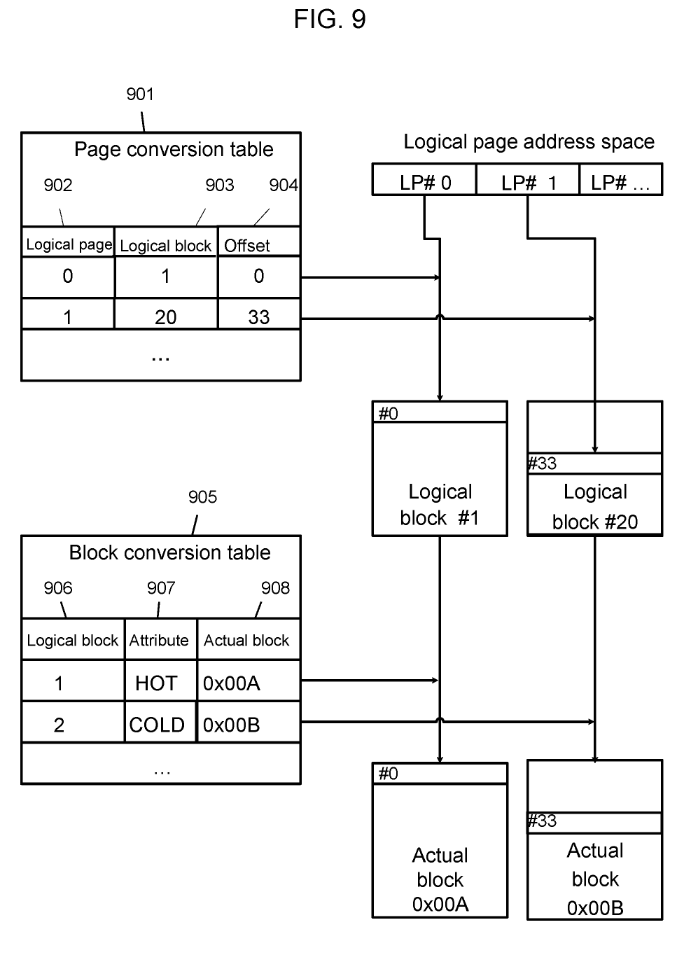

The page conversion table 901 retains page-based conversion information. The details of the page conversion table 901 will be described later (see FIG. 9).

The block conversion table 905 retains block-based conversion information. The details of the block conversion table 905 will be described later (see FIG. 9).

The logical/physical conversion program 305 specifies a physical page (a physical address) of the FM 210, corresponding to a logical page (for example, LBA) of a logical volume designated by a read command and a write command received from the higher-level apparatus 102. The logical/physical conversion program 305 converts a logical page (LBA) of a logical volume to a physical page (a physical address) of the FM 210 or vice versa by referring to the page conversion table 901 and the block conversion table 905.

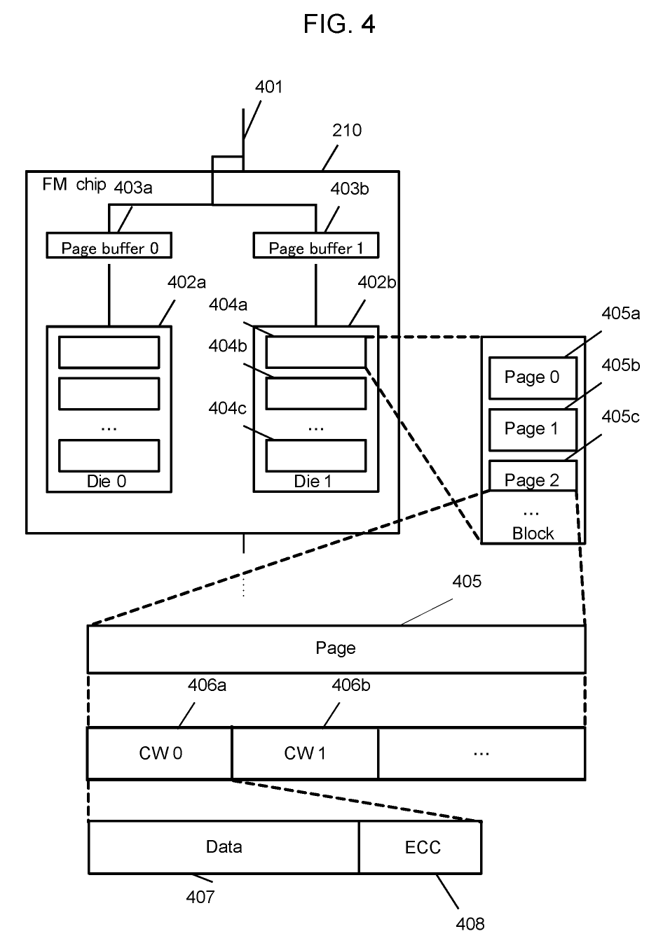

FIG. 4 illustrates a configuration example of the FM 210.

One or more FMs 210 are coupled to an FM bus 401. The FM 210 includes a plurality of page buffers 403a and 403b and a plurality of dies 402a and 402b. Die 2402 has a plurality of physical blocks 404. The physical block 404 has a plurality of physical pages 405. As described above, the physical page 405 is the unit of data read/write. The physical block 404 is the unit of data erasure.

Write data issued from the FM controller 201 is temporarily stored in the page buffer 403. The write data of the page buffer 403 is stored in the physical page 405.

The data stored in the physical page 405 of the FM 201 cannot be rewritten directly. Due to this, the FM controller 201 rewrites data in the following manner. The FM controller 201 copies the data in a rewrite target physical page 405 to the main memory 207 and rewrites the data on the main memory 207. The FM controller 201 stores the rewritten data in another free physical page 405 and invalidates the rewrite target physical page 405. A read command, a write command, and an erase command with respect to the FM 210 may be issued by the FM I/F 209.

One or more Code Words (CW) 406 may be stored in the physical page 405. The CW 406 may include a data portion 407 and an Error Correcting Code (ECC) 408 for protecting the data portion 407. The ECC 408 is information for correcting a bit error of the data portion 407, which can occur during data transfer between the FM controller 201 and the FM 210.

The volume of the data portion 407 may be “n-th power of 2 (2ⁿ)” bytes (n is a positive integer). The volume of the ECC 408 may be a bytes (a is a positive integer). In this case, the volume of the CW 406 may be “n-th power of 2 (2ⁿ)+α” bytes. The data portion 407 may be user data received from the higher-level apparatus 102, metadata used for control, or a combination thereof.

The capacity of the physical page 405 may be “2 KB+α”, “4 KB+α”, “8 KB+α”, or the like. The number of physical pages 405 included in the physical block 404 may be “128 pages”, “256 pages”, or the like.

The FM 210 may include a controller and a DMA associated with a data transfer process and an assist circuit associated with a data read/write process.

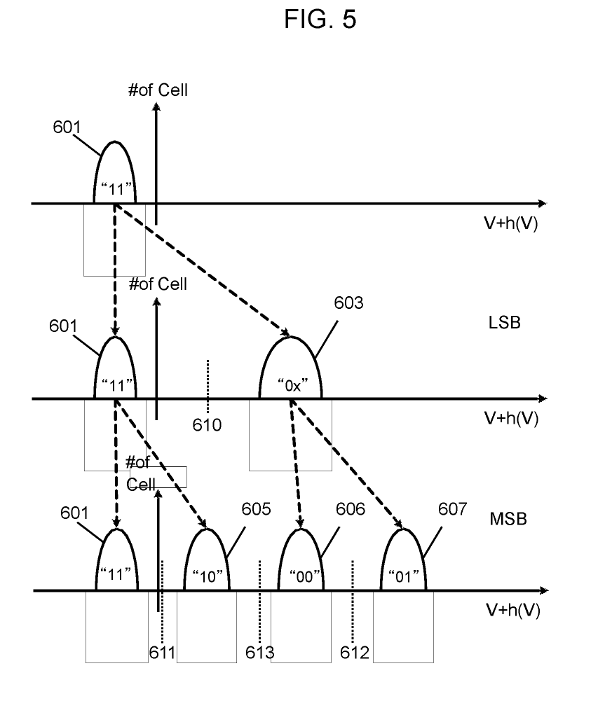

FIG. 5 illustrates a storage example of data in an FM of a Multiple Level Cell (MLC).

When data is stored in an FM of an MLC, two bits of data can be stored in the same cell, for example. The left-side bit of the two bits (“11b”) of the same cell is referred to as a Least Significant Bit (LSB) and the right-side bit is referred to as a Most Significant Bit (MSB).

Symbol 601 indicates a state (the state of a cell in which data has been erased) in which a charge is not retained in a floating gate of a cell. The cell in which data has been erased is denoted by “11b”. Arrows in FIG. 5 indicate a transition of a charge distribution state.

When data “10b” is to be stored to a cell in the state (“11b”) indicated by symbol 601, a predetermined charge is applied to the cell to create a state indicated by symbol 605.

When data “00b” is to be stored to a cell in the state (“11b”) indicated by symbol 601, a predetermined charge is applied to the cell to create a state indicated by symbol 603 first. After that, a predetermined charge is applied thereto to create a state (“00b”) indicated by symbol 606.

When data “01b” is to be stored to a cell in the state (“11b”) indicated by symbol 601, a predetermined charge is applied to the cell to create a state indicated by symbol 603 first. After that, a predetermined charge is applied thereto to create a state (“01b”) indicated by symbol 607.

In this manner, when data is stored in an FM of an MLC, there may be a case where two process steps are required.

Next, a method of reading the LSB of a cell will be described.

When the LSB of a cell is read, a readout voltage 610 having a magnitude near an intermediate value between the values indicated by symbols 601 and 603 is applied. When this readout voltage 610 was applied, it can be determined that the LSB of this cell is “1b” (symbol 601) if a predetermined current flows and the LSB of this cell is “0b” (symbol 603) if a predetermined current does not flow.

Next, a method of reading the MSB of a cell will be described.

When the MSB of a cell is read, first, a readout voltage 613 having a magnitude near an intermediate value between the values indicated by symbols 605 and 606 is applied, and it is determined whether a predetermined current flows.

Subsequently, if a predetermined current flows when the readout voltage 613 was applied, a readout voltage 611 having a magnitude near an intermediate value between the values indicated by symbols 601 and 605 is applied. When the readout voltage 611 was applied, the MSB of this cell is “1b” if a predetermined current flows, and the MSB of this cell is “0b” if a predetermined current does not flow.

Subsequently, if a predetermined current does not flow when the readout voltage 613 was applied, a readout voltage 612 having a magnitude near an intermediate value between the values indicated by symbols 606 and 607 is applied. When the readout voltage 612 was applied, the MSB of this cell is “0b” if a predetermined current flows, and the MSB of this cell is “1b” if a predetermined current does not flow.

In this manner, when the MSB is read from an FM of an MLC, two process steps are required.

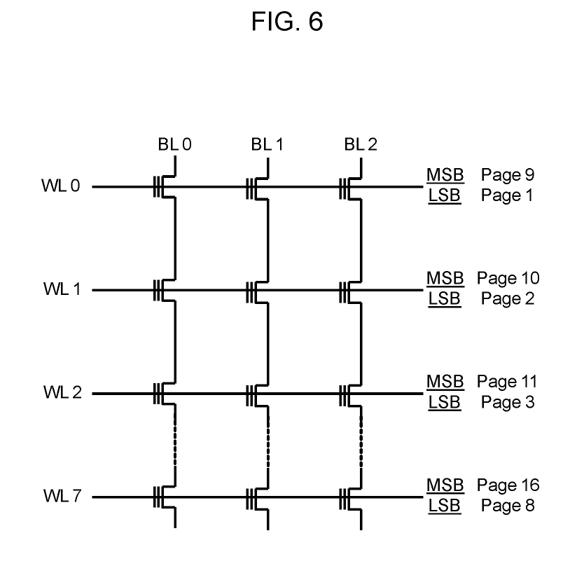

FIG. 6 illustrates a configuration example of a cell of the PM 210.

The FM 210 can write data in units of the physical pages 405. When data is stored in one physical page 405 only, the potential of each cell is likely to be unstable due to intercell interference. The potential of each cell is likely to be stable when data is stored in a plurality of physical pages 405. For example, intercell interference is more likely to decrease when data is stored in all physical pages 405 in the physical block 404 than when data is stored in a small number of physical pages 405.

In FIG. 6, a physical page “1” is composed of a bit string of the LSBs of respective cells (BitLines (BLs) 0 to 2) on a WordLine (WL) 0, and a physical page “9” is composed of a bit string of the MSBs of respective cells (BLs 0 to 2) on the same WL 0.

A case in which data is stored in the order of physical page numbers like physical pages “1”, “2”, and “3” will be described. In this case, the LSB only is written to respective cells (BLs 0 to 2) on the WL 0 until data is stored in the physical page “9” (the MSB on WL 0) after data is stored in the physical page “1” (the LSB on WL 0). In this state, the cell potential is likely to be unstable and the intercell interference is likely to increase as compared to a state in which the MSB is also written.

Therefore, the FMPKG 113-1 according to the embodiment collectively stores data in all physical pages (or a predetermined number or more of physical pages of the physical block) of the physical block. In this way, it is possible to shorten the time of an unstable state in which the LSB only is written to a cell. Moreover, it is possible to shorten the time in which a physical page (a cell) in which data is written is adjacent to a physical page (a cell) in which data is not written. That is, it is possible to suppress intercell interference.

The range of intercell interference depends on a physical distance between cells. In the embodiment, the range of intercell interference will be described to be within the range of one physical block. That is, in the embodiment, it is described that intercell interference between different physical blocks is sufficient small. However, even if intercell interference reaches across different physical blocks, the content of the embodiment can be realized by rephrasing the range of the physical block 404 referred in the embodiment as the range of intercell interference.

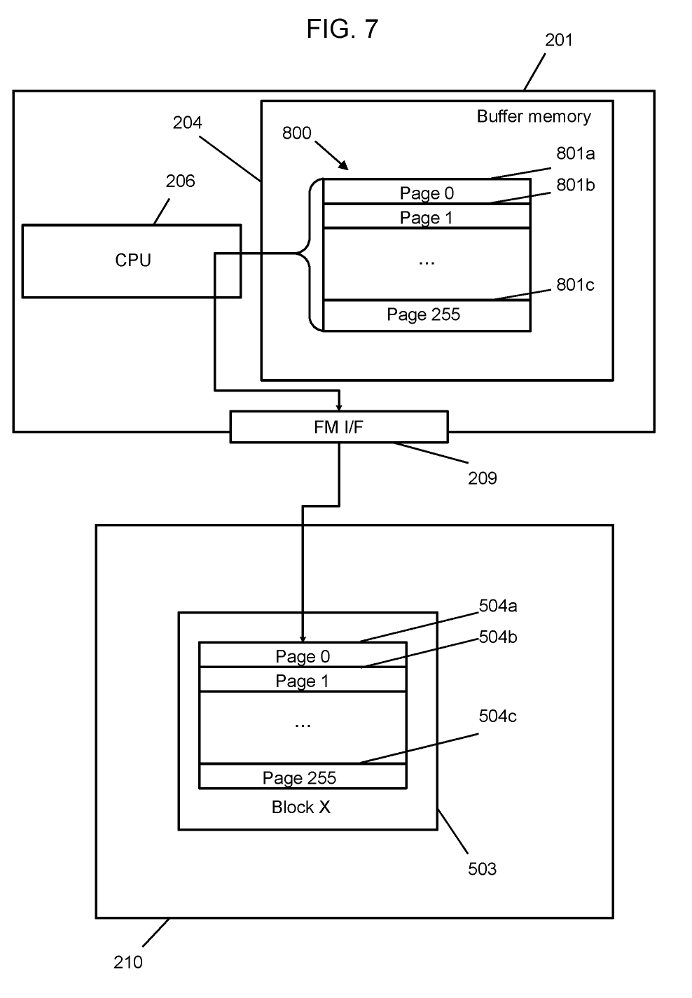

FIG. 7 illustrates a processing example of transferring data to the FM 210 in the FMPKG 113-1.

(S11) The FM controller 201 secures a buffer block area 800 in the buffer memory 204. The buffer block area 800 is an area for temporarily storing write data to be written to the FM 210. The buffer block area 800 may be composed of a plurality of buffer pages 801a to 801c. The capacity of one buffer block area 800 may be the same as the capacity of one physical block 404. Moreover, the capacity of one buffer page 801 may be the same as the capacity of one physical page 405. The number of buffer pages 801 that form one buffer block area 800 may be the same as the number of physical pages 405 that forms one physical block 404.

(S12) The FM controller 201 stores the write data received from the higher-level apparatus 102 in the buffer page 801 of the buffer block area 800.

(S13) The FM controller 201 collectively transfers all pieces of data in the buffer block area 800 to the physical block 404 of the FM 210 when data is stored in all buffer pages 801 (or a predetermined number or more of buffer pages 801) of the buffer block area 800. That is, the pieces of data in the buffer block area 800 are collectively stored in the physical block 404 of the FM 210.

In this way, since the LSB and the MSB are collectively written to the physical page 405, an unstable time in which the LSB only is written to the physical page 405 (the cell) can be shortened. Moreover, the time in which the physical page 405 (the cell) in which data is written and the physical page 405 (the cell) in which data is not written are adjacent to each other can be shortened as compared to a case in which data is written to the individual physical pages 405 of the physical block 404. That is, it is possible to suppress intercell interference.

In S13, the FM controller 201 may collectively transfer the data in a plurality of buffer block areas 800 to a plurality of physical blocks 404.

Moreover, when a volume of data equal to or larger than the capacity of the physical block 404 is stored in the buffer memory 204, the FM controller 201 may collectively transfer a volume of data corresponding to the capacity of the physical block 404 to the physical block 404 of the FM 210. When data is collectively transferred, the FM controller 201 may designate a starting address of the buffer block area 800 as a transfer source address and a starting address of the physical block 404 as a transfer destination address.

In the following description, an area corresponding to the buffer block area 800 is sometimes referred to as a primary storage area, and an area corresponding to the physical block 404 is sometimes referred to as a secondary storage area. That is, the primary storage area is an area in which write data is temporarily stored, and the secondary storage area is an area in which write data is finally stored.

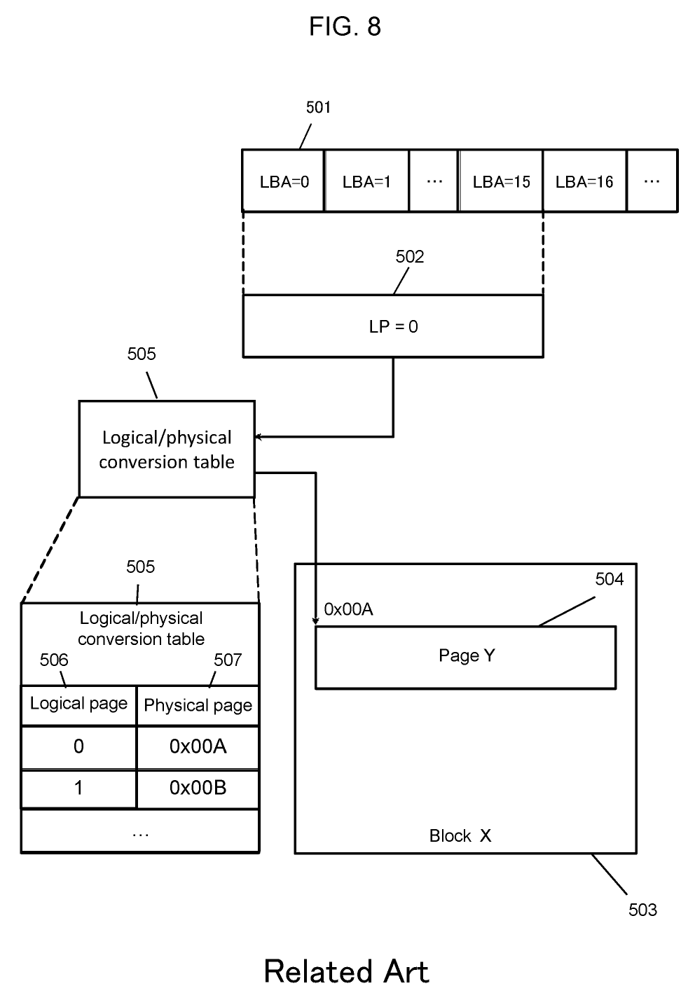

FIG. 8 illustrates a configuration example of a conventional logical/physical conversion table.

A conventional logical/physical conversion table 505 retains correspondence information between the logical page 506 provided to the higher-level apparatus and the physical page 507 in which data is stored actually. In the conventional logical/physical conversion table 505, the logical page 506 and the physical page 507 are correlated in one-to-one correspondence.

FIG. 9 illustrates a configuration example of the block conversion table 905 and the page conversion table 901.

In order to realize physical block-based data transfer from a primary storage area to a secondary storage area, the FMPKG 113-1 includes the block conversion table 905 and the page conversion table 901 as tables corresponding to the conventional logical/physical conversion table 505.

The page conversion table 901 retains page-based conversion information. The page conversion table 901 may retain information indicating the correspondence relation between a logical page number 902, a number 903 of a logical block in which a logical page corresponding to the logical page number 902, and an offset value 904 which is the position in the logical block of the logical page.

The block conversion table 905 retains block-based conversion information. The block conversion table 905 may retain information indicating a correspondence relation between a logical block number 906, an attribute 907, and an actual block address 908.

The attribute 907 is information indicating the frequency (update frequency) of a write command with respect to a logical block corresponding to the logical block number 906. For example, the attribute 907 may be “HOT” if the logical block corresponding to the logical block number 906 has an update frequency equal to or higher than a predetermined upper limit threshold, and the attribute 907 may be “COLD” if the logical block has an update frequency lower than a predetermined lower limit threshold. In this way, it is possible to aggregate data according to the attribute 907 and the FMPKG 113-1 can perform a wear leveling process efficiently. The attribute 907 may take a plurality of different values according to the update frequency without being limited to the two values of HOT and COLD.

The actual block 908 is an address indicating a reference destination storage area of the logical block corresponding to the logical block number 906. The actual block 908 may be the address of the buffer block area 800 (the primary storage area) or the address of the physical block 404 (the secondary storage area). When the actual block 908 is the address of the buffer block area 800, data associated with the logical block corresponding to the logical block number 906 indicates that data has not been transferred to the FM 210. When the actual block 908 is the address of the physical block 404, data associated with the logical block corresponding to the logical block number 906 indicates that data has been transferred to the FM 210.

The actual block 908 and the physical block 404 may be correlated in one-to-one correspondence and may be correlated in one-to-N correspondence (N is a positive integer of 2 or more). The physical block 404 corresponding to the actual block 908 may be fixed and may be changed. By setting the physical block 404 corresponding to the actual block 908 so as to be changeable, it is possible to efficiently cope with faults in physical blocks, perform a wear leveling process, and utilize resources.

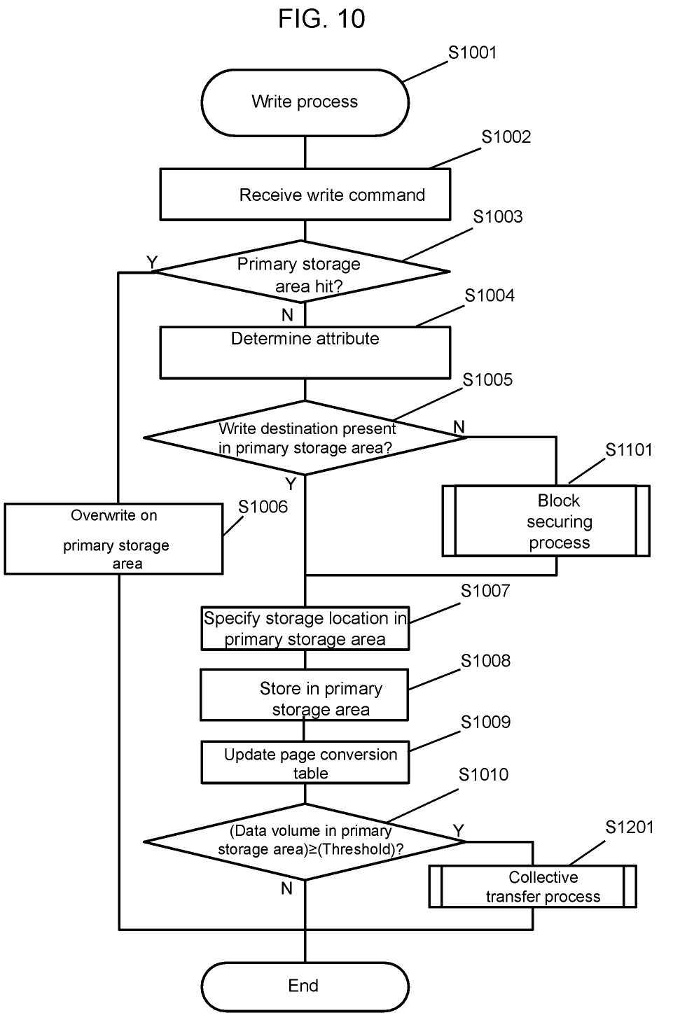

FIG. 10 illustrates an example of a flowchart of a write process in the FMPKG 113-1.

(S1002) Upon receiving a write command from the higher-level apparatus 102, the FM controller 201 proceeds to S1003.

(S1003) The FM controller 201 determines whether the actual block 908 associated with the logical page 902 designated by the write command is present in the primary storage area. The flow proceeds to S1006 when the determination result is positive (YES) and the flow proceeds to S1004 when the determination result is negative (NO).

(S1006) When the determination result in S1003 is positive (YES), the FM controller 201 rewrites the data in the actual block 908 associated with the logical page 902 with the write data associated with the write command on the primary storage area. After that, this process ends.

(S1004) When the determination result in S1003 is negative (NO), the FM controller 201 performs the following process in order to store write data in the primary storage area. The FM controller 201 specifies the attribute (HOT or COLD) of the write data. After that, the flow proceeds to S1005.

(S1005) The FM controller 201 determines whether the actual block 908 having the attribute 907 suitable for the attribute of the write data specified in S1004 is present. The FM controller 201 proceeds to S1007 when the determination result is positive (YES) and proceeds to S1101 when the determination result is negative (NO).

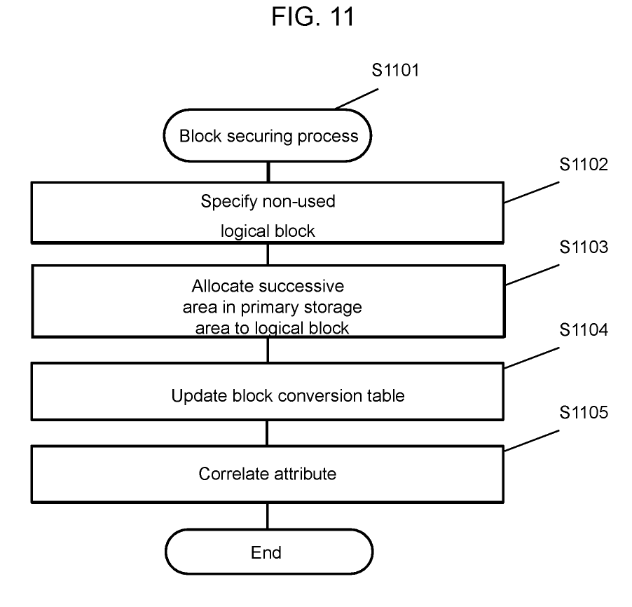

(S1101) When the determination result in S1005 is negative (NO), the FM controller 201 performs a block securing process. By this process, the actual block 908 having the attribute 907 suitable for the attribute of the write data specified in S1004 is secured. The details of this process will be described later (see FIG. 11). After that, the flow proceeds to S1007.

(S1007) The FM controller 201 specifies a storage destination of the write data in the primary storage area. That is, the position of the offset 904 in an area corresponding to the actual block 908 is specified. After that, the flow proceeds to S1008.

(S1008) The FM controller 201 stores the write data in the specified storage destination of the primary storage area. After that, the flow proceeds to S1009.

(S1009) The FM controller 201 updates the page conversion table 901. In this case, the FM controller 201 may update a pointer to a logical block indicating the next storage destination, the number of pieces of valid data in the logical block, statistic information, and the like. The statistic information may include information on a write frequency of the logical block or the logical page. After that, the flow proceeds to S1010.

(S1010) The FM controller 201 determines whether the volume of write data stored in the primary storage area is equal to or larger than a predetermined threshold. This threshold may be equal to or larger than the capacity of one physical block 404. The FM controller 201 proceeds to S1201 when the determination result is positive (YES) and this process ends when the determination result is negative (NO).

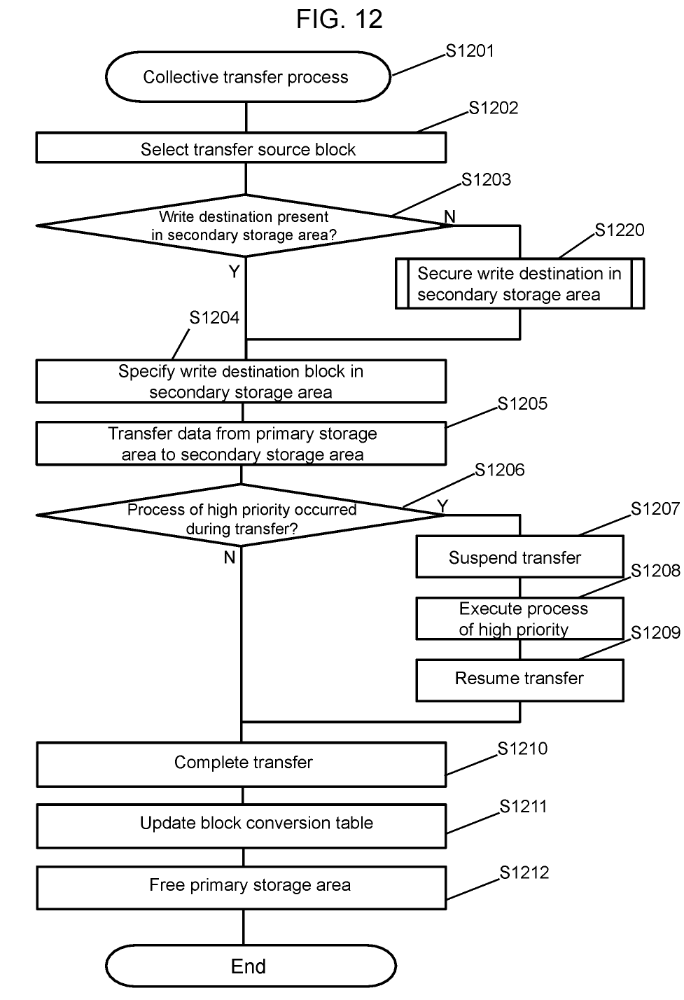

(S1201) When the determination result in S1010 is positive (YES), the FM controller 201 executes a collective transfer process. That is, a volume of write data corresponding to the capacity of one physical block 404 stored in the primary storage area is collectively transferred to the physical block 404 of the FM 210. The details of this process will be described later (see FIG. 12). The FM controller 201 may delete pieces of write data which have been transferred collectively from the primary storage area. In this way, the free space of the primary storage area increases. After that, this process ends.

The FM controller 201 may return a completion response to the write command to the higher-level apparatus 102 at an arbitrary timing. The FM controller 201 may return the completion response immediate after the write data is received when latency to the higher-level apparatus 102 is to be increased. The FM controller 201 may return the completion response after the write data is stored in the FM 210 when the risk of data loss due to power shutdown or the like is to be decreased (reliability is to be increased). Moreover, although not illustrated in this flowchart, the FM controller 201 may perform read-modified write when the volume of the write data is equal to or smaller than the capacity of the logical page.

FIG. 11 illustrates an example of a flowchart of a block securing process. This process is the details of S1101 in FIG. 10.

(S1102) The FM controller 201 specifies a non-used logical block. A non-used logical block may be a logical block which is not correlated with any actual block. The FM controller 201 may manage non-used logical blocks using a FIFO-type queue. After that, the flow proceeds to S1103.

(S1103) The FM controller 201 allocates a successive area (the buffer block area 800) on the primary storage area to the specified non-used logical block. After that, the flow proceeds to S1104.

(S1104) The FM controller 201 updates the block conversion table 905. That is, in the block conversion table 905, the address of the allocated successive area is correlated with the number 906 of the specified logical block as the actual block 908. After that, the flow proceeds to S1105.

(S1105) The FM controller 201 correlates the attribute (for example, HOT/COLD) of the write data specified in S1004 in FIG. 10 with the number 906 of the specified logical block in the block conversion table 905 as the attribute 907. After that, the write data having the same attribute as this attribute 907 may be stored in this specified logical block.

FIG. 12 illustrates an example of a flowchart of a collective transfer process. This process is the details of S1201 in FIG. 10.

(S1202) The FM controller 201 selects the actual block 908 (the buffer block area 800) serving as a transfer source from the block conversion table 905. The FM controller 201 may preferentially select the buffer block area 800 in which the write data is stored in all buffer pages 801. Alternatively, the FM controller 201 may select the transfer source buffer block area 800 on the basis of the attribute 907. For example, the actual block 908 (the buffer block area 800) corresponding to the attribute 907 (COLD) having a low write frequency may be selected preferentially. This is because the write data stored in the actual block 908 (the buffer block area 800) corresponding to the attribute 907 (HOT) having a high write frequency is highly likely to hit in S1003 in FIG. 10 and is to be retained in the buffer block area 800 as long as possible.

(S1203) The FM controller 201 determines whether an empty physical block 404 is present in the secondary storage area. The FM controller 201 proceeds to S1204 when the determination result is positive (YES) and proceeds to S1220 when the determination result is negative (NO).

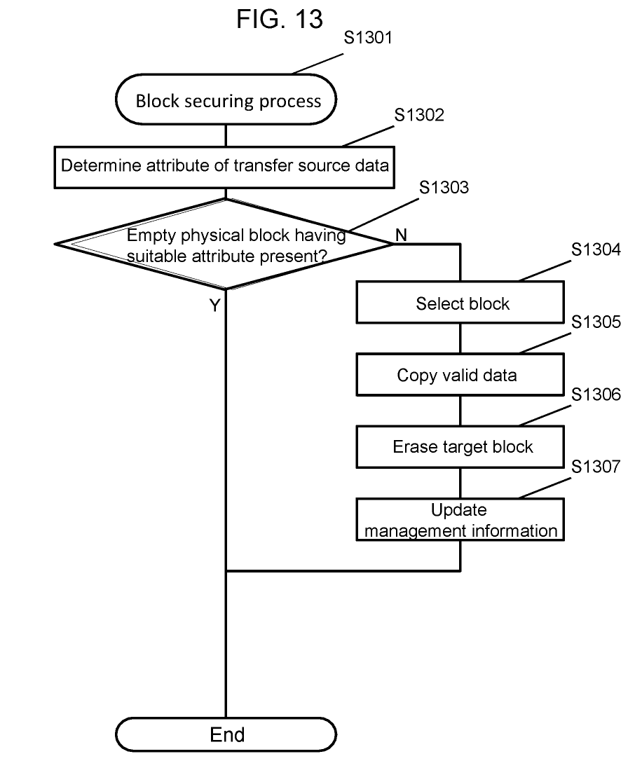

(S1220) When the determination result in S1203 is negative (NO), the FM controller 201 secures an empty physical block 404 in the secondary storage area. The details of this process will be described later (see FIG. 13). After that, the flow proceeds to S1204.

(S1204) The FM controller 201 selects a transfer destination empty physical block 404 in the secondary storage area. When wear leveling is taken into consideration, the FM controller 201 may select the empty physical block 404 suitable for the attribute 907 (HOT/COLD) corresponding to the transfer source actual block 908. After that, the flow proceeds to S1205.

(S1205) The FM controller 201 starts a process of collectively transferring all pieces of data stored in the transfer source buffer block area 800 to the transfer destination empty physical block 404. After that, the flow proceeds to S1206.

(S1206) The FM controller 201 determines whether a process of a higher priority than collective transfer has occurred during the collective transfer. The FM controller 201 proceeds to S1207 when the determination result is positive (YES) and proceeds to S1210 when the determination result is negative (NO). A process of a high priority is a read process which requires resources occupied for transfer or a process of updating data being transferred, for example. When a process of updating data being transferred is detected, the FM controller 201 may store the note thereof using a flag or the like and update the data after transfer is completed. Alternatively, when a process of updating data being transferred is detected, the FM controller 201 may update data in the buffer block area 800 and perform collective transfer again.

(S1207) When the determination result in S1206 is positive (YES), the FM controller 201 temporarily stops the collective transfer. This is because the collective transfer takes a considerable time for completion of transfer since the data volume of the collective transfer is larger than that of page-based transfer. After that, the flow proceeds to S1208.

(S1208) The FM controller 201 executes a process of a high priority. After that, the flow proceeds to S1209.

(S1209) The FM controller 201 resumes collective transfer after the process of a high priority is completed. After that, the flow proceeds to S1210.

(S1210) The FM controller 210 proceeds to S1211 upon detecting completion of the collective transfer.

(S1211) The FM controller 201 updates the block conversion table. That is, the transfer target actual block 908 is changed from the address of the transfer source buffer block area 800 to the address of the transfer destination physical block 404. Here, update of the page conversion table is not necessary. This is because the offset 904 in the logical block of each logical page does not change in the transfer destination physical block 404. After that, the flow proceeds to S1212.

(S1212) The FM controller 201 frees the transfer source buffer block area 800. After that, this process ends.

If the conventional logical/physical conversion table was used, it is necessary to change the address of the transfer source to the address of the transfer destination in respective pages in S1211. In contrast, in the above-described process, in S1211, it is only necessary to change the address of the transfer source to the address of the transfer destination in respective blocks. That is, according to the present embodiment, it is possible to decrease the number of times the table is updated.

FIG. 13 illustrates an example of a flowchart of a process of securing the empty physical block 404 in a secondary storage area. This process is details of S1220 in FIG. 12.

(S1302) The FM controller 201 determines the attribute (HOT/COLD) of transfer source data.

(S1303) The FM controller 201 determines whether an empty physical block having the attribute 907 suitable for the attribute determined in S1302 is present. The FM controller 201 ends this process when the determination result is positive (YES), and proceeds to S1304 when the determination result is negative (NO).

(S1304) When the determination result in S1303 is negative (NO), the FM controller 201 selects the physical block 404 which is a target of a reclamation process. The physical block 404 which is a target of the reclamation process selected among the physical blocks 404 having the attribute 907 suitable for the attribute determined in S1302 may be a physical block in which the percentage of invalid data is the highest. After that, the flow proceeds to S1305.

(S1305) The FM controller 201 copies valid data in the selected physical block 404 to another physical block 404. After that, the flow proceeds to S1306.

(S1306) The FM controller 201 erases data in the selected original physical block 404. After that, the flow proceeds to S1307.

(S1307) The FM controller 201 updates predetermined management information for the erases physical block 404. After that, this process ends.

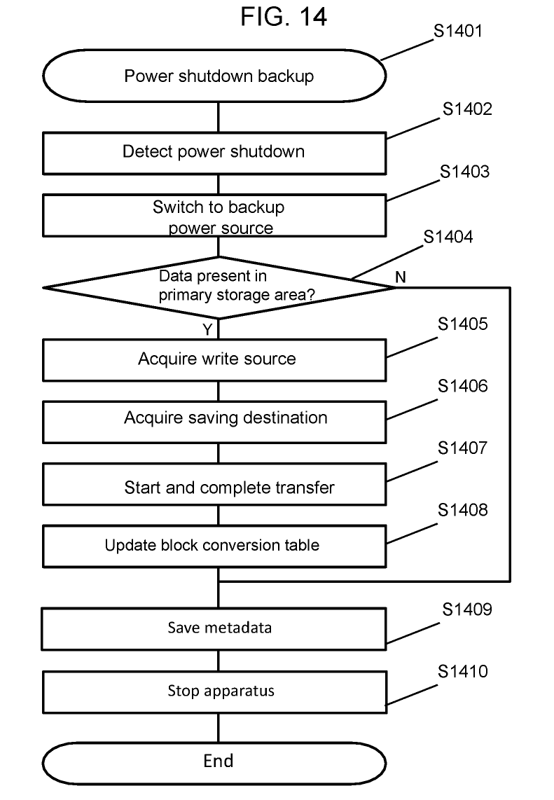

FIG. 14 illustrates an example of a flowchart of a process of saving data in the buffer memory 204 when power shutdown occurs.

When the buffer memory 204 is configured as a volatile storage medium and power shutdown occurs, it is necessary to transfer the data in the buffer memory 204 to an FM in a period in which electric power is supplied from the battery 205.

(S1402) When the FM controller 201 detects the occurrence of power shutdown, the FM controller 201 proceeds to S1403.

(S1403) The FM controller 201 switches a power supply source to the battery 205. After that, the flow proceeds to S1404.

(S1404) The FM controller 201 determines whether data is present in the buffer block area 800. The FM controller 201 proceeds to S1405 when the determination result is positive (YES) and proceeds to S1409 when the determination result is negative (NO).

(S1405 to S1408) When the determination result in S1404 is positive (YES), the FM controller 201 collectively transfers all pieces of data in the buffer block area 800 to the physical block 404 of the FM 210 and updates the block conversion table 905. After that, the flow proceeds to S1409.

(S1409 to S1410) The FM controller 201 saves metadata in the FM 210 and stops operations. The FM controller 201 may collectively transfer write data and metadata to the FM 210 without discriminating them.

When the volume of data in the buffer block area 800 is smaller than the capacity of one physical block 404, the FM controller 201 may add dummy data to the data in the buffer block area 800 so that the data volume is equal to the capacity of one physical block 404. The dummy data is preferably random data. Random data is data in which bit values are arranged randomly. This is because intercell interference when random data is used is smaller than that when data in which same bit values are arranged is used. The FM controller 201 may collective transfer pieces of data to which the dummy data is added to the physical block 404 of the FM 210. In this way, it is possible to reduce intercell interference similarly to the above.

Moreover, the FMPKG 113-2 may further have a nonvolatile memory in preparation for an emergency situation of a high urgency level such as power shutdown and may save the data in the buffer block area 800 in the nonvolatile memory. Alternatively, the FMPKG 113-2 may prepare an FM of an emergency SLC in a portion of the FM 210 and may save the data in the buffer block area 800 in the FM of the SLC. This is because the FM of the SLC is faster and produces less intercell interference than the FM of an MLC.

### Embodiment 2

Embodiment 2 illustrates an example in which a primary storage area (a buffer block area) is a nonvolatile memory.

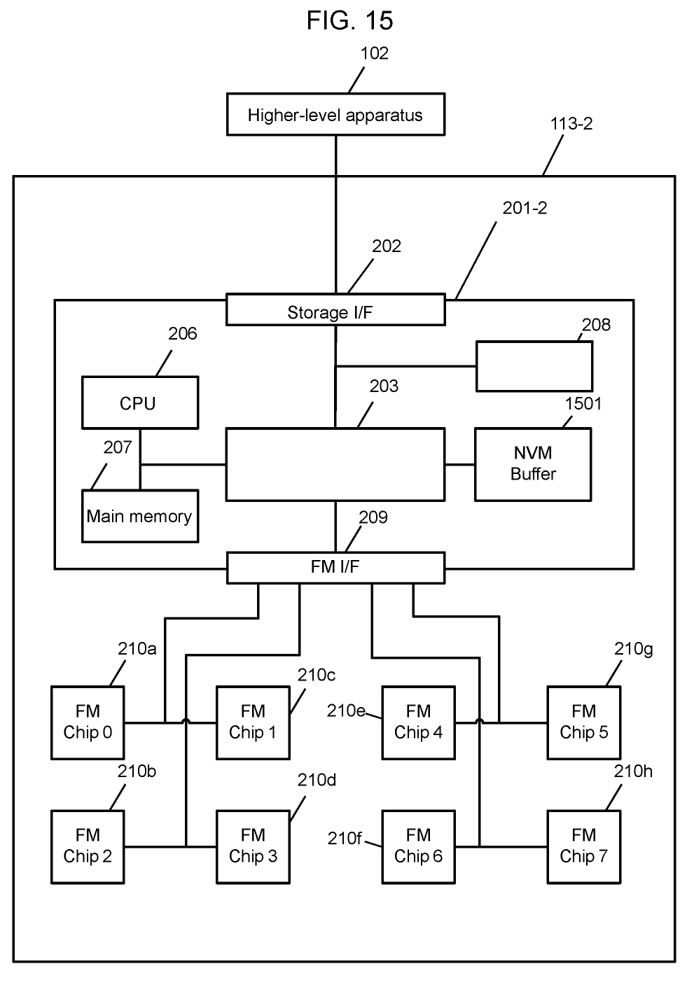

FIG. 15 illustrates a configuration example of an FMPKG 113-2 according to Embodiment 2.

The FMPKG 113 has a nonvolatile memory 1501 for a primary storage area. The nonvolatile memory 1501 has a buffer block area. The FMPKG 113-2 may have a DRAM (not illustrated). Metadata and the like which require high-speed access may be stored in the DRAM.

The nonvolatile memory 1501 may be configured to read and write data in predetermined units of pages. Moreover, the nonvolatile memory 1501 may be configured to erase data in predetermined units of blocks. The nonvolatile memory that forms the primary storage area may produce less intercell interference than the FM that forms the secondary storage area. That is, it may not be necessary to take intercell interference into consideration with regard to writes of data in a primary storage area. Examples of such a nonvolatile memory that forms the primary storage area include an FM of an SLC, a Resistance Random Access Memory (ReRAM), a Magnetoresistive Random Access Memory (MRAM), a Phase Change Memory (PCM), and the like.

The capacity of one page of the nonvolatile memory 1501 may be smaller than the capacity of one physical page 405 of the FM 210 that forms the secondary storage area. The numbers (life span) of writable and erasable times of the nonvolatile memory 1501 may be larger than those of the FM 210.

In Embodiment 2, the data stored in the primary storage area is retained even if power shutdown occurs. Therefore, even if power shutdown occurs, it is not necessary to save the data in the primary storage area like the process illustrated in FIG. 14 of Embodiment 1. However, in preparation for the occurrence of power shutdown during collective transfer from the primary storage area to the secondary storage area, the FM controller 201-2 may manage buffer block areas during collective transfer. When power shutdown occurs during collective transfer, the FM controller 201-2 may erase data having been transferred in the physical block 404 of the secondary storage area after recovery.

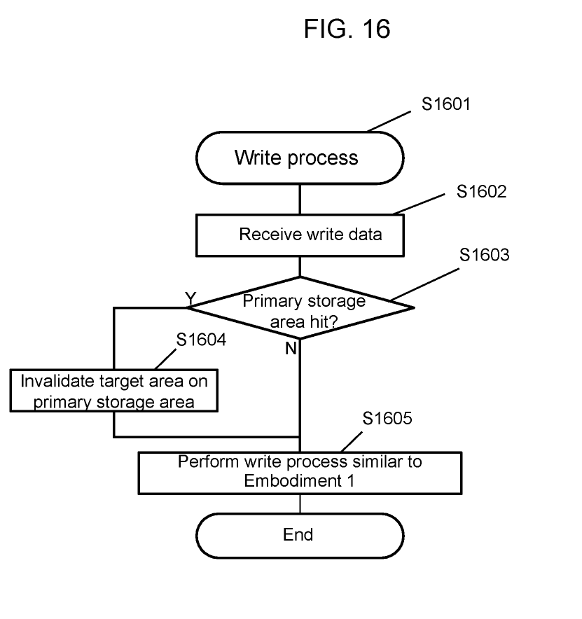

FIG. 16 illustrates an example of a flowchart of a write process in the FMPKG 113-2 according to Embodiment 2.

(S1602) Upon receiving a write command from the higher-level apparatus 102, the FM controller 201-2 proceeds to S1603.

(S1603) The FM controller 201-2 determines whether an actual block 908 associated with a logical page 902 designated by the write command is present in the primary storage area. The flow proceeds to S1604 when the determination result is positive (YES) and proceeds to S1605 when the determination result is negative (NO).

(S1604) When the determination result in S1603 is positive (YES), the FM controller 201-2 invalidates a buffer page corresponding to the actual block 908 of the primary storage area. Invalidation is a process of removing the correspondence relation between the logical page 902 and the buffer block area and the offset 804 in the page conversion table 901 and decrementing the number of valid pages in the buffer block area. The FM controller 201-2 stores newly received write data in another buffer block area of the primary storage area. After that, the flow proceeds to S1605.

(S1605) The FM controller 201 performs processes similar to S1004 and subsequent processes in FIG. 10 and stores the write command in the primary storage area.

The buffer page in the primary storage area may be invalidated at a timing at which the write data has been stored in the primary storage area and the page conversion table 901 and the block conversion table 905 are updated.

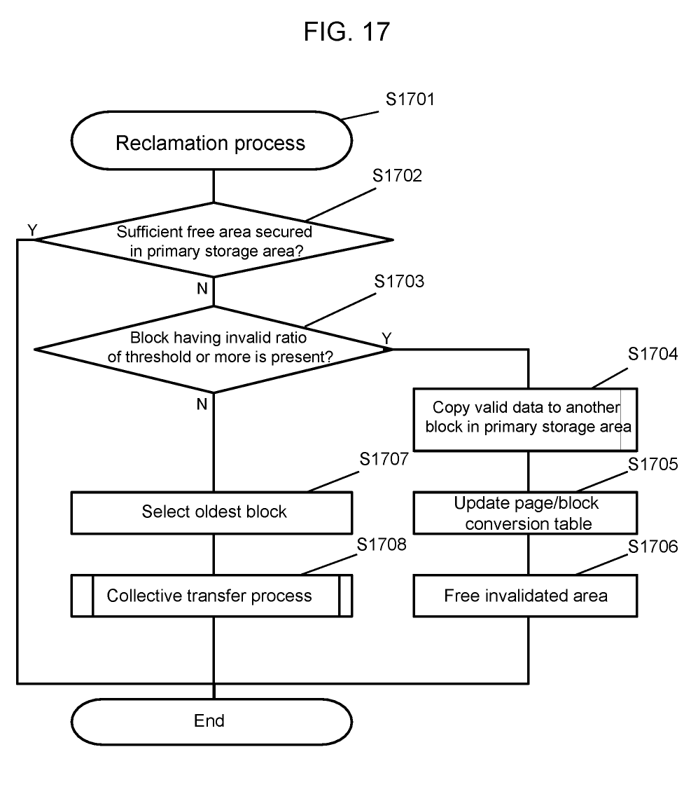

FIG. 17 illustrates an example of a flowchart of a reclamation process in the primary storage area.

In Embodiment 2, as illustrated in FIG. 16, invalid pages and fragmentation may occur in the primary storage area. Therefore, the FM controller 201-2 may perform a reclamation process on the primary storage area. The reclamation process may be performed when a free area in the primary storage area is not sufficient.

(S1702) The FM controller 201-2 determines whether a free area in the primary storage area is smaller than a predetermined threshold. The flow proceeds to S1703 when the determination result is positive (YES) and this process ends when the determination result is negative (NO). The threshold may be set to be equal to or larger than a capacity capable of storing a volume of write data which can occur in a burst.

(S1703) The FM controller 201-2 determines whether a buffer block area in which the number of invalid pages is equal to or larger than a predetermined threshold (number, percentage, or the like) is present in the primary storage area. The flow proceeds to S1704 when the determination result is positive (YES) and proceeds to S1707 when the determination result is negative (NO).

(S1704 to S1706) When the determination result in S1703 is positive (YES) (that is, a buffer block area in which the number of invalid pages is equal to or larger than a predetermined threshold is present), the FM controller 201 copies valid data in the buffer block area to another buffer block area and erases all pieces of data in the copy source buffer block area. After that, this process ends.

(S1707 to S1708) When the determination result in S1703 is negative (NO) (that is, a buffer block area in which the number of invalid pages is equal to or larger than a predetermined threshold is not present), the FM controller 201-2 collective transfers pieces of data in the buffer block area to the secondary storage area in order from oldest to newest. After that, this process ends. A reclamation process in the secondary storage area may be performs similarly to Embodiment 1.

In this way, when the percentage of invalid data in the primary storage area is equal to or larger than a threshold, the reclamation process is performed whereby it is possible to increase a free area while allowing write data to remain in the primary storage area as long as possible. When the percentage of invalid data is smaller than the threshold, since the free area does not increase too much even if the reclamation process is performed, the data in the primary storage area is transferred to the secondary storage area. In this way, it is possible to increase a free area in the primary storage area.

The FM controller 201-2 may transfer data in the primary storage area including valid data to the secondary storage area after a reclamation process is performed on the primary storage area. In this way, since the data transferred includes a large number of pieces of valid data (does not include such a large number of pieces of invalid data), the transfer efficiency of valid data from the primary storage area to the secondary storage area is improved. Moreover, the load of a reclamation process in the secondary storage area is reduced.

### Embodiment 3

Embodiment 3 illustrates an example in which both a primary storage area and a secondary storage area are provided in the FM 210. The primary storage area may produce less intercell interference and have a smaller unit area for write than the secondary storage area. The FM of an SLC may form the primary storage area and the FM of an MLC may form the secondary storage area. Alternatively, in the FM 210 of the MLC, the primary storage area may be formed using the LSB only and the secondary storage area may be formed using LSB and MSB. Hereinafter, an area formed using LSB only or the SLC will be referred to as an “SLC area”, and an area formed using both LSB and MSB or the MLC will be referred to as an “MLC area”.

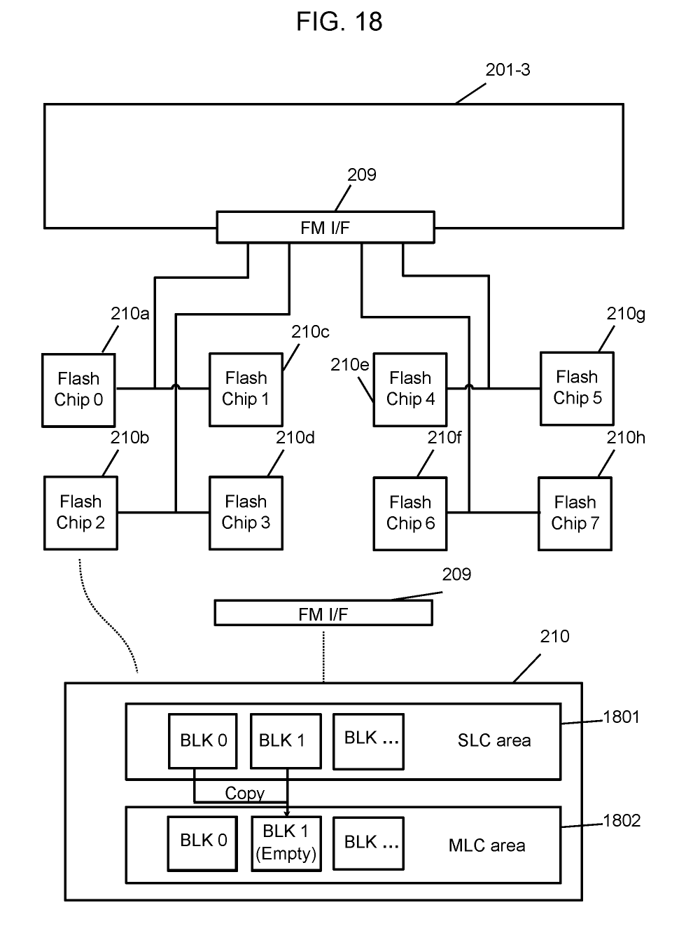

FIG. 18 illustrates a configuration example of an FMPKG 113-3 according to Embodiment 3.

The FM 210 has an SLC area 1801 and an MLC area 1802. The FMPKG 113 uses the SLC area 1801 as a primary storage area and uses the MLC area 1802 as a secondary storage area.

The FMPKG 113-3 may collectively transfer data from the SLC area 1801 to the MLC area 1802 via an FM I/F 209.

The FM 210 may have a collectively transfer circuit and may collectively transfer data from the SLC area 1801 to the MLC area 1802 via the circuit. In this case, the FM I/F 209 may issue a transfer command that designates a transfer source physical block and a transfer destination physical block to the FM. The FM I/F 209 may designate the physical blocks of a plurality of SLC areas 1801 as a transfer source when the capacity of a physical block of the MLC area 1802 is larger than the capacity of a physical block of the SLC area 1801. The FM I/F 209 may receive a transfer completion notification from the FM. The collective transfer circuit may be provided inside an FM chip and may be provided outside the FM chip and may be shared by a plurality of FM chips.

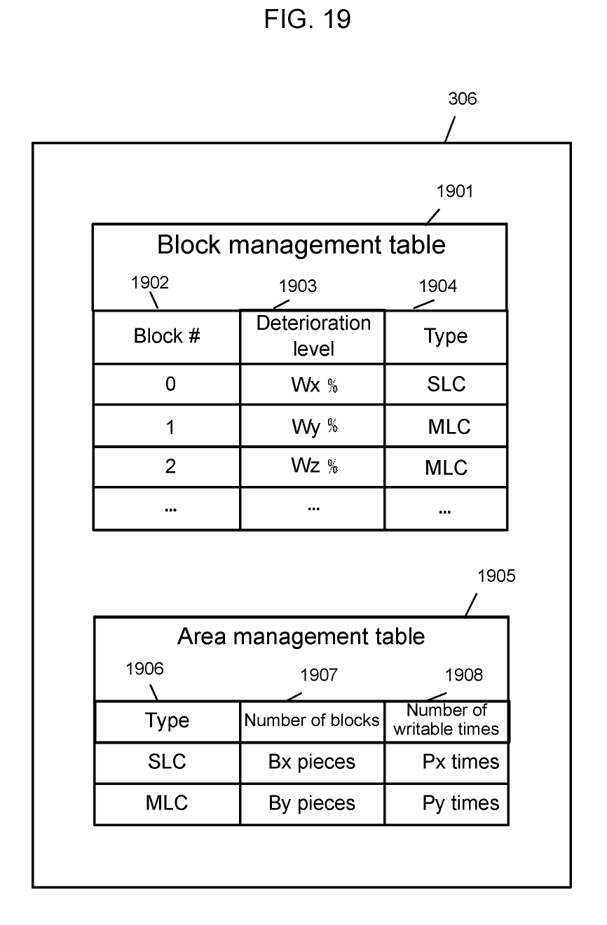

FIG. 19 illustrates a configuration example of a block management table 1901 and an area management table 1905.

The block management table 1901 retains information on respective physical blocks. The block management table 1901 may have a block number 1902, a deterioration level 1903, and a type 1904 as item values (column values).

The block number 1902 is an identification number of a physical block.

The deterioration level 1903 indicates the degree (service life) of deterioration of a physical block corresponding to the block number 1902. As described above, a data retention ability of a physical block deteriorates as the number of writes (a write frequency) and the number of erasures (an erasure frequency) increase. For example, if the deterioration level of a physical block reaches 100%, the physical block cannot retain data sufficiently and has reaches its service life. The deterioration level 1903 may be calculated on the basis of a read error rate of data stored in a physical block.

The type 1904 indicates whether the physical block corresponding to the block number 1902 is the SLC area 1801 or the MLC area 1802.

The area management table 1905 retains information associated with the SLC area 1801 and the MLC area 1802. The area management table 1905 may have a type 1906, the number of blocks 1907, and the number of writable times 1908 as an item value (column value).

The type 1906 indicates whether a record retains information associated with the SLC area 1801 or the MLC area 1802.

The number of blocks 1907 indicates the number of physical blocks that form an area indicated by the type 1906. That is, the number of blocks 1907 indicates the capacity of an area indicated by the type 1906.

The number of writable times 1908 indicates the number of times (frequency) data can be written to an area indicated by the type 1906. The number of writable times 1908 may be calculated on the basis of the deterioration levels 1903 of respective physical blocks 404 that form an area indicated by the type 1906.

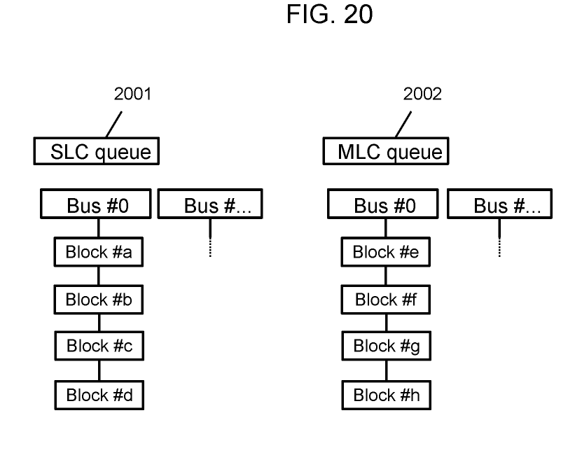

FIG. 20 illustrates a configuration example of an SLC queue 2001 and an MLC queue 2002.

The FMPKG 113-3 may manage physical blocks that form the SLC area 1801 using the SLC queue 2001. The FMPKG 113-3 may manage physical blocks that form the MLC area 1802 using the MLC queue 2002.

The FMPKG 113-3 may have an empty physical block queue, an invalid physical block queue, and a valid physical block queue with respect to the SLC area 1801 and the MLC area 1802.

The number of an empty physical block may be linked to an empty physical block queue. The empty physical block is a physical block in which data has been erased. The empty physical block queue may be sorted in descending (or ascending) order of deterioration levels of physical blocks. This is to perform a wear leveling process efficiently.

The number of an invalid physical block may be linked to an invalid physical block queue. An invalid physical block is a physical block in which data can be erased.

The number of a valid physical block may be linked to the valid physical block queue. The valid physical block is a physical block including data (valid pages) that cannot be erased. The valid physical block queue may be sorted in descending (or ascending) of the number of invalid physical pages in the physical block. This is to perform a reclamation process efficiently.

Moreover, the FMPKG 113-3 may have these queues in respective driving units (for example, buses) of FM chips. This is to easily acquire block sets for obtaining multiplicity of FM chips.

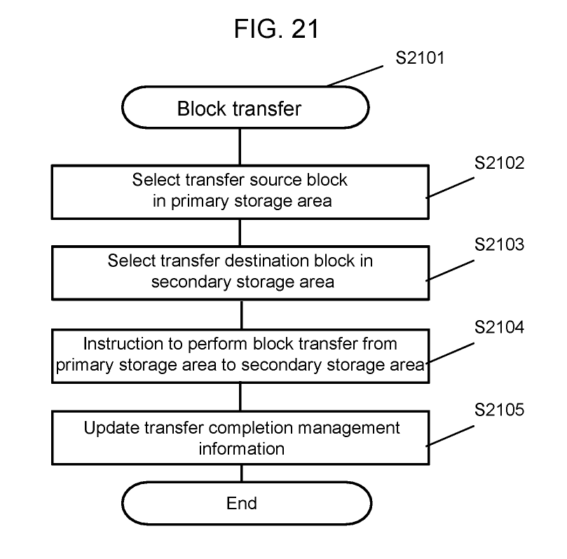

FIG. 21 illustrates an example of a flowchart of a collective transfer process according to Embodiment 3.

The FMPKG 113-3 may perform collective transfer from the primary storage area to the secondary storage area when a free area in the primary storage area is not sufficient. In this case, the FMPKG 113-3 may perform a reclamation process with respect to the primary storage area.

(S2102) The FM controller 201-3 selects a transfer source physical block (corresponding to a buffer block area) from the primary storage area. The FM controller 201-3 may preferentially select a physical block in which the time elapsed after writing is the longest. Alternatively, the FM controller 201-3 may preferentially select a physical block in which the percentage of the number of invalid pages is the smallest (the percentage of the number of valid pages is the largest). This is because such a physical block is not likely to be a target of a reclamation process in the primary storage area and the valid data transfer efficiency is high. Alternatively, the FM controller 201-3 may select a transfer source physical block on the basis of a combination of these plural conditions. After that, the flow proceeds to S2103.

(S2103) The FM controller 201-3 selects a transfer destination empty physical block from the secondary storage area. In this case, when an empty physical block cannot be secured in the secondary storage area or the number of empty physical blocks in the secondary storage area is equal to or smaller than a threshold, the FM controller 201-3 may perform a reclamation process with respect to the secondary storage area. After that, this flow proceeds to S2104.

(S2104) The FM controller 201-3 issues an instruction to perform collective transfer from the primary storage area to the secondary storage area. This collective transfer may be performed inside the FM as described above in FIG. 18. In this case, the FM I/F 209 may issue the transfer instruction to the FM. When a command of a higher priority than the transfer process is issued to an FM which is performing collective transfer, the FM I/F 209 may issue a collective transfer suspension command to the FM similarly to Embodiment 1. After that, the flow proceeds to S2105.

(S2105) Upon receiving a transfer completion notification, the FM controller 201 updates the area management table 1905. After that, this process ends.

When power shutdown occurs during collective transfer, the FM controller 201-3 may erase data having been transferred in the physical block of the secondary storage area after recovery similarly to Embodiment 2.

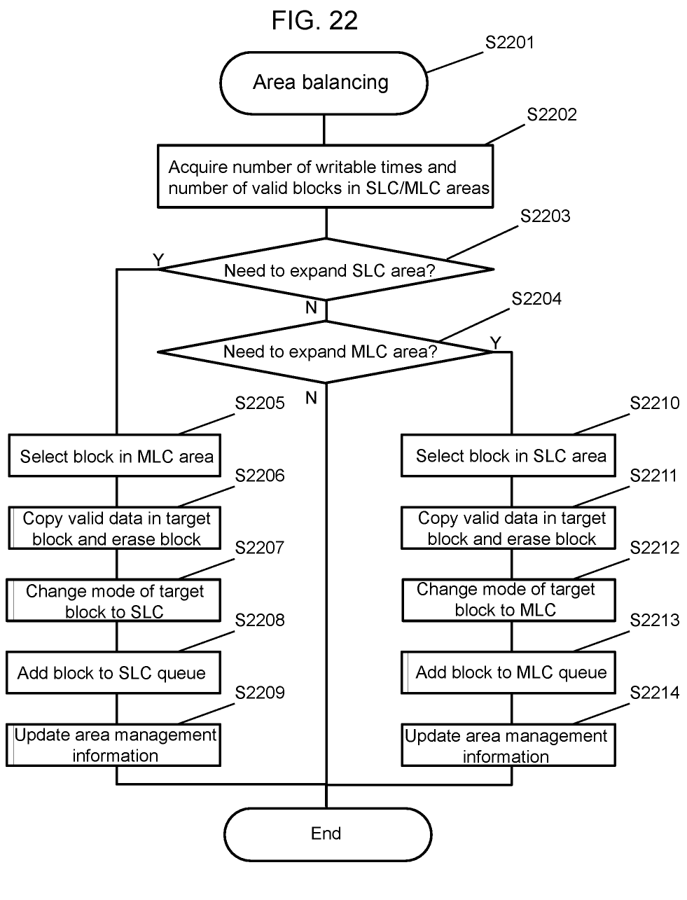

FIG. 22 illustrates an example of a flowchart of a process of adjusting the number of physical blocks between the SLC area 1801 and the MLC area 1802.

(S2202) The FM controller 201-3 acquires information on respective areas from the area management table 1905. The FM controller 201-3 analyzes a deterioration state of each area on the basis of the acquired information and determines the number of physical blocks in each area. For example, the FM controller 201-3 may determine the number of physical blocks in each area so that the numbers of writable times 1908 in respective area are equalized. Moreover, when the same number of physical blocks is allocated, since the capacity of the SLC area 1801 becomes smaller than the capacity of the MLC area 1802, the FM controller 201-3 may determine the number of physical blocks in each area so that the SLC area 1801 and the MLC area 1802 have predetermined capacities, respectively. In this case, the capacity may be determined so that the capacity of a logical volume to be provided to the higher-level apparatus 102 can be secured. Moreover, the capacities may be determined by taking a preliminary area for the reclamation process into consideration. These capacities may be determined on the basis of requirements such as the efficiency of the reclamation process.

(S2203) The FM controller 201-3 determines whether it is necessary to expand the SLC area 1801. The FM controller 201-3 proceeds to S2205 when the determination result is positive (YES) and proceeds to S2204 when the determination result is negative (NO).

(S2205) When the determination result in S2203 is positive (YES), the FM controller 201-3 may select a mode change target physical block from the MLC area 1802. When the number of writable times in the SLC area 1801 is smaller than a predetermined threshold, the FM controller 201-3 may select a physical block in which the deterioration level is the lowest (or smaller than a predetermined threshold) from the MLC area 1802. In this case, the FM controller 201 may take a migration source physical block into consideration so that the numbers of physical blocks in the SLC area are equal in respective driving units of FM chips by taking the multiplicity of operations of FM chips into consideration. After that, the flow proceeds to S2206.

(S2206) When valid data is included in the selected physical block, the FM controller 201-3 copies the valid data in another physical block and erases all pieces of data in the selected physical block. After that, the flow proceeds to S2207.

(S2207) The FM controller 201-3 changes to a mode in which the selected physical block is used as the SLC area 1801. After that, the flow proceeds to S2208.

(S2208) The FM controller 201-3 adds the number of the selected block to the SLC queue 2001.

(S2209) The FM controller 201-3 updates block management information 1901. After that, this process ends.

(S2204) When the determination result in S2203 is negative (NO), the FM controller 201-3 determines whether it is necessary to expand the MLC area 1802. The FM controller 201-3 proceeds to S2210 when the determination result is positive (YES) and this process ends when the determination result is negative (NO).

(S2210 to S2214) When the determination result in S2204 is positive (YES), the FM controller 201-3 expands the MLC area 1802 similarly to S2205 to S2209. After that, this process ends.

The above-described embodiment of the present invention is an example for describing the present invention, and the scope of the present invention is not limited to the embodiment only. An ordinary person in the art can implement the present invention in various other aspects without departing from the spirit of the present invention.

The inventions according to the embodiments can be expressed as follows.

(Expression 1)

A flash memory package comprising: a controller; and at least one memory including a flash memory, wherein

the flash memory includes a plurality of physical blocks, each of the physical blocks is the unit of data erasure, the physical blocks each include a plurality of physical pages, and each of the physical pages is the unit of data write, and
the controller:
stores received write data in a primary storage area, which is a partial storage area of the memory;
sets the unit of storage area including the plurality of physical pages as the unit of collective transfer to perform collective transfer; and
when a volume of data accumulated in the primary storage area is equal to or larger than a capacity of one unit of collective transfer of the flash memory, collectively transfers a volume of data corresponding to the capacity of at least one unit of collective transfer from the primary storage area to a secondary storage area, which is a partial storage area of the flash memory.

(Expression 2)

The flash memory package according to Expression 1, further comprising:

page management information including information indicating a relation between a position of a logical page and a logical block; and
block management information including information indicating a relation between a logical block and a data storage destination area, wherein
the data storage destination area in the block management information is the primary storage area or the secondary storage area.

(Expression 3)

The flash memory package according to Expression 2, wherein the controller changes the data storage destination in the block management information from the primary storage area to the secondary storage area during the collective transfer.

(Expression 4)

The flash memory package according to Expression 3, wherein the block management information further includes at least information indicating a frequency of a write request to the logical block, and

the controller collectively transfers preferentially data in the primary storage area associated with a logical block in which the frequency of the write request is relatively low to the secondary storage area.

(Expression 5)

The flash memory package according to Expression 4, wherein the controller selects, as a destination of the collective transfer, a secondary storage area in which an erasure frequency is relatively low, as the frequency of the write request becomes relatively higher.

(Expression 6)

The flash memory package according to any one of Expressions 1 to 5, wherein

upon receiving an I/O request of a higher priority than the collective transfer during the collective transfer, the controller temporarily suspends the collective transfer.

(Expression 7)

The flash memory package according to any one of Expressions 1 to 6, wherein

the primary storage area is a NAND-type flash memory and includes a plurality of physical blocks, the physical blocks each including a plurality of physical pages, and
the secondary storage area is a NAND-type flash memory that stores more data per a cell rather than that of the primary storage area.

(Expression 8)

The flash memory package according to Expression 7, wherein the controller collectively transfers data in the primary storage area including valid data to the secondary storage area after a reclamation process is performed on the primary storage area.

(Expression 9)

The flash memory package according to Expression 7 or 8, wherein when the number of free physical pages in the primary storage area is smaller than a predetermined threshold, the controller determines whether a physical block in which a percentage of invalid data is equal to or larger than a predetermined threshold is present in the primary storage area, performs a reclamation process on the primary storage area when the determination result is positive, and collectively transfers data in the primary storage area including valid data to the secondary storage area when the determination result is negative.

(Expression 10)

The flash memory package according to any one of Expressions 1 to 9, wherein

when the volume of data accumulated in the primary storage area is smaller than the capacity of one unit of collective transfer of the flash memory, the controller adds, to the data in the primary storage area, a volume of random data with which the volume of data in the primary storage area becomes equal to or larger than the capacity of one unit of collective transfer, and collectively transfers, to the secondary storage area, a volume of data corresponding to the capacity of at least one unit of collective transfer after addition of the random data.

(Expression 11)

The flash memory package according to any one of Expressions 1 to 10, wherein

the primary storage area is a partial storage area of the flash memory,
the primary storage area is an area in which a physical block is used in an SLC mode, and
the secondary storage area is an area in which a physical block is used in a mode with a larger storage capacity per a cell rather than that of the primary storage area.

(Expression 12)

The flash memory package according to Expression 11, wherein the controller:

changes a physical block in which an erasure frequency is equal to or larger than a first threshold in the primary storage area, to the secondary storage area in which the physical block is used in the MLC mode; and
changes a physical block in which an erasure frequency is smaller than a second threshold in the secondary storage area, to the primary storage area in which the physical block is used in the SLC mode, the first threshold being larger than the second threshold.

(Expression 13)

A storage system including a flash memory package, the storage system including: a storage controller; and a flash memory package, wherein

the flash memory package includes: a flash memory controller; and at least one memory including a flash memory,
the flash memory includes a plurality of physical blocks, each of the physical blocks is the unit of data erasure, the physical blocks each include a plurality of physical pages, and each of the physical pages is the unit of data write, and
the flash memory controller:
stores write data received from the storage controller in a primary storage area, which is a partial storage area of the memory; set the unit of storage area including the plurality of physical pages as the unit of collective transfer to perform collective transfer; and
when a volume of data accumulated in the primary storage area is equal to or larger than a capacity of one unit of collective transfer of the flash memory, the storage controller collectively transfers a volume of data corresponding to the capacity of at least one unit of collective transfer from the primary storage area to a secondary storage area, which is a partial storage area of the flash memory.

### REFERENCE SIGNS LIST

101 Storage system
102 Storage controller
113 Flash memory package
201 Flash memory controller
204 Buffer memory
210 Flash memory

1. A flash memory package comprising: a controller; and at least one memory including a flash memory, wherein
the flash memory includes a plurality of physical blocks, each of the physical blocks is the unit of data erasure, the physical blocks each include a plurality of physical pages, and each of the physical pages is the unit of data write, and
the controller is configured to:
store received write data in a primary storage area, which is a partial storage area of the memory;
set the unit of storage area including the plurality of physical pages as the unit of collective transfer to perform collective transfer; and
when a volume of data accumulated in the primary storage area is equal to or larger than a capacity of one unit of collective transfer of the flash memory, collectively transfer a volume of data corresponding to the capacity of at least one unit of collective transfer from the primary storage area to a secondary storage area, which is a partial storage area of the flash memory.

2. The flash memory package according to claim 1, further comprising:
page management information including information indicating a relation between a position of a logical page and a logical block; and
block management information including information indicating a relation between a logical block and a data storage destination area, wherein
the data storage destination area in the block management information is the primary storage area or the secondary storage area.

3. The flash memory package according to claim 2, wherein
the controller is configured to change the data storage destination in the block management information from the primary storage area to the secondary storage area during the collective transfer.

4. The flash memory package according to claim 3, wherein
the block management information further includes at least information indicating a frequency of a write request to the logical block, and
the controller is configured to collectively transfer preferentially data in the primary storage area associated with a logical block in which the frequency of the write request is relatively low to the secondary storage area.

5. The flash memory package according to claim 4, wherein
the controller is configured to select, as a destination of the collective transfer, a secondary storage area in which an erasure frequency is relatively low, as the frequency of the write request becomes relatively higher.

6. The flash memory package according to claim 1, wherein
the controller is configured to, upon receiving an I/O request of a higher priority than the collective transfer during the collective transfer, temporarily suspend the collective transfer.

7. The flash memory package according to claim 1, wherein
the primary storage area is a NAND-type flash memory and includes a plurality of physical blocks, the physical blocks each including a plurality of physical pages, and
the secondary storage area is a NAND-type flash memory configured to store more data per a cell rather than that of the primary storage area.

8. The flash memory package according to claim 7, wherein
the controller is configured to collectively transfer data in the primary storage area including valid data to the secondary storage area after a reclamation process is performed on the primary storage area.

9. The flash memory package according to claim 7, wherein
the controller is configured to, when the number of free physical pages in the primary storage area is smaller than a predetermined threshold, determine whether a physical block in which a percentage of invalid data is equal to or larger than a predetermined threshold is present in the primary storage area, perform a reclamation process on the primary storage area when the determination result is positive, and collectively transfer data in the primary storage area including valid data to the secondary storage area when the determination result is negative.

10. The flash memory package according to claim 1, wherein
the controller is configured to, when the volume of data accumulated in the primary storage area is smaller than the capacity of one unit of collective transfer of the flash memory, add, to the data in the primary storage area, a volume of random data with which the volume of data in the primary storage area becomes equal to or larger than the capacity of one unit of collective transfer, and collectively transfer, to the secondary storage area, a volume of data corresponding to the capacity of at least one unit of collective transfer after addition of the random data.

11. The flash memory package according to claim 1, wherein
the primary storage area is a partial storage area of the flash memory,
and
the secondary storage area is an area in which a physical block is used in a mode with a larger storage capacity per a cell rather than that of the primary storage area.

12. The flash memory package according to claim 11, wherein
the controller is configured to:
change a physical block in which an erasure frequency is equal to or larger than a first threshold in the primary storage area, to the secondary storage area in which the physical block is used in the mode with the larger storage capacity per the cell rather than that of the primary storage area; and
change a physical block in which an erasure frequency is smaller than a second threshold in the secondary storage area, the first threshold being larger than the second threshold.

13. A storage system including a flash memory package, the storage system comprising: a storage controller; and a flash memory package, wherein
the flash memory package includes: a flash memory controller; and at least one memory including a flash memory,
the flash memory includes a plurality of physical blocks, each of the physical blocks is the unit of data erasure, the physical blocks each include a plurality of physical pages, and each of the physical pages is the unit of data write, and
the flash memory controller is configured to:
store write data received from the storage controller in a primary storage area, which is a partial storage area of the memory;
set the unit of storage area including the plurality of physical pages as the unit of collective transfer to perform collective transfer; and
when a volume of data accumulated in the primary storage area is equal to or larger than a capacity of one unit of collective transfer of the flash memory, collectively transfer a volume of data corresponding to the capacity of at least one unit of collective transfer from the primary storage area to a secondary storage area, which is a partial storage area of the flash memory.
